(19) United States
(12) Patent Application Publication
(10) Pub. No.: US 2026/0253835 A1
(43) Pub. Date: Aug. 27, 2026

(54) SCANNING ELECTRON MICROSCOPE AND PHOTOMULTIPLIER THEREFOR AND METHOD OF EVALUATING A SAMPLE

(71) Applicant: Applied Materials Israel Ltd., Rehovot (IL)

(72) Inventor: Eitam Yitzchak Vinegrad, Rehovot (IL)

(73) Assignee: Applied Materials Israel Ltd., Rehovot (IL)

(21) Appl. No.: 19/064,567

(22) Filed: Feb. 26, 2025

(51) Int. Cl. H01J 37/26; H01J 37/244; H01J 37/28

(52) U.S. Cl. CPC H01J 37/265; H01J 37/244; H01J 37/28; H01J 2237/2441; H01J 2237/2443; H01J 2237/2445; H01J 2237/24495; H01J 2237/2814

(57) ABSTRACT

A scanning electron microscope (SEM) configured to scan a sample by irradiating it with a plurality of source particles. The SEM comprises a particle detector comprising a photomultiplier, the photomultiplier is configured to detect emitted particles from the sample and comprises a sensor surface having a plurality of cells each configured to detect one or more particles impinging thereon and to produce an output signal indicative of a quantity of impinging particles. The SEM further comprises a controller configured to define a plurality of zones each associated with one or more of the cells. The controller is further configured to calculate the magnitude of a triggering event based on the sum of output signals produced within a predetermined time interval by the cells within each of one or more of the zones. The geometry of the zones facilitates evaluating one or more properties of the sample.

### TECHNICAL FIELD

The presently disclosed subject matter relates to metrology systems configured to evaluate one or more properties of a sample by detecting particles emitted thereby when irradiated by one or more source particles, and in particular to scanning electron microscopes.

### BACKGROUND OF THE INVENTION

Scanning electron microscopes are used to evaluate properties of a sample by irradiating it with source particles, and detecting particles produced by the sample when so irradiated. They typically comprise photomultipliers, for example, in conjunction with a scintillator, for the detection.

### BRIEF SUMMARY OF THE INVENTION

According to an aspect of the presently disclosed subject matter, there is provided a scanning electron microscope (SEM) configured to scan a sample by irradiating it with a plurality of source particles, the SEM comprising a particle detector comprising:
a photomultiplier configured to detect emitted particles from the sample (i.e., produced by the sample when impinged upon by the source particles), the photomultiplier comprising a sensor surface comprising a plurality of cells, each of the cells being configured to detect one or more particles impinging thereon and to produce an output signal indicative of a quantity of impinging particles; and
a controller configured to define a plurality of zones, each of the zones being associated with one or more of the cells, the controller being further configured to calculate the magnitude of a triggering event based on the sum of output signals produced within a predetermined time interval by the cells within each of one or more of the zones;
wherein the geometry of the zones facilitates evaluating one or more properties of the sample.

According to another aspect of the presently disclosed subject matter, there is provided an inspection system to inspect a sample by irradiating it with a plurality of source particles, the inspection system comprising a particle detector comprising:
a photomultiplier configured to detect emitted particles from the sample (i.e., produced by the sample when impinged upon by the source particles), the photomultiplier comprising a sensor surface comprising a plurality of cells, each of the cells being configured to detect one or more particles impinging thereon and to produce an output signal indicative of a quantity of impinging particles; and
a controller configured to define a plurality of zones, each of the zones being associated with one or more of the cells, the controller being further configured to calculate the magnitude of a triggering event based on the sum of output signals produced within a predetermined time interval by the cells within each of one or more of the zones;
wherein the geometry of the zones facilitates evaluating one or more properties of the sample.

The inspection system may be configured to facilitate identification and detection of defects on the sample, measuring features of the sample (e.g., constituting or comprising a metrology system), measuring contrast, measuring absolute gray level, and/or produce images of the sample.

Either of the above aspects may be characterized as provided below.

The geometry of the zones may facilitate determining the surface topography of a sample.

The geometry of the zones may facilitate determining the angle of incidence of the emitted particles.

The geometry of the zones may facilitate determining energy dispersion of a plurality of the emitted particles.

The particle detector may further comprise a scintillator configured to be impinged upon by the emitted particles and to emit a number of photons proportional to the energy of the emitted particles, the photomultiplier being configured to indirectly detect the emitted particles by detecting the photons emitted by the scintillator impinging thereon.

The duration of the time interval may be at least partially based on an operating speed of the scintillator.

The duration of the time interval may be at least partially based on a scanning speed of the inspection system/SEM. For example, the time interval may be equal to the dwell time, i.e., the amount of time that each area of the sample corresponding to a pixel is irradiated by source particles.

The duration of the time interval may be measured from production of a first output signal by a cell within the zone.

Each of the cells may be associated with no more than one of the zones.

The controller may be configured to redefine the zones.

The controller may be configured to analyze data regarding a set of output signals from the cells, and to calculate, based on the set of output signals, the magnitudes of a plurality of triggering events within overlapping time segments.

The controller may be configured to analyze data regarding a set of output signals from the cells, and to calculate, based on the set of output signals, the magnitudes of a plurality of triggering events based on a plurality of zone definitions.

Each of the cells may comprise one or more microcells, each microcell comprising:
a single-photon avalanche diode configured to detect a photon; and
a quenching arrangement configured to quench and reset the microcell.

The quenching arrangement may be configured for active quenching, e.g., wherein the photomultiplier is a digital silicon photomultiplier. According to some examples, the active quenching arrangement may be configured to introduce a delay between quenching and resetting the microcell.

The quenching arrangement may comprise a quenching resistor.

The output signal may be indicative of at least one particle impinging prior to the microcell being reset.

Each of the microcells may be configured to produce a plurality of output signals within the time interval.

Each of the cells may comprise a single microcell, the photomultiplier being configured to provide information correlating each microcell with an output signal produced thereby.

The controller may be configured to selectively disregard the output signal produced by one or more predetermined microcells.

The controller may be configured to disregard triggering events in which output signals were produced by fewer than a predetermined number of microcells.

According to another aspect of the presently disclosed subject matter, there is provided a particle detector as described above, mutatis mutandis.

According to another aspect of the presently disclosed subject matter, there is provided a method for evaluating one or more properties of a sample when irradiated by an inspection system, e.g., a scanning electron microscope, with a plurality of source particles, the method comprising:
receiving one or more output signals from a photomultiplier, the photomultiplier being configured to detect emitted particles produced by the sample when impinged upon by the source particles, the photomultiplier comprising a sensor surface comprising a plurality of cells, each of the cells being configured to detect one or more particles impinging thereon and to produce one of the output signals being indicative of a quantity of impinging particles;
defining a plurality of zones of the sensor surface, each of the zones being associated with one or more of the cells; and
calculating the magnitude of a triggering event based on the sum of output signals produced within a predetermined time interval by the cells within each of one or more of the zones; and
evaluating the one or more properties of the sample based on the magnitudes of the one or more triggering events and on the geometry of the zones.

The geometry of the zones may facilitate determining the surface topography of a sample.

The geometry of the zones may facilitate determining the angle of incidence of the emitted particles.

The geometry of the zones may facilitate determining energy dispersion of a plurality of the emitted particles.

The particle detector may further comprise a scintillator configured to be impinged upon by the emitted particles and to emit a number of photons proportional to the energy of the emitted particles, the photomultiplier being configured to indirectly detect the emitted particles by detecting the photons emitted by the scintillator impinging thereon.

The duration of the time interval may be at least partially based on an operating speed of the scintillator.

The duration of the time interval may be at least partially based on a scanning speed of the inspection system.

The time interval may be equal to the dwell time.

The duration of the time interval may be measured from production of a first output signal by a cell within the zone.

Each of the cells may be associated with no more than one of the zones.

The method may further comprise redefining the zones.

The method may further comprise analyzing data regarding a set of output signals from the cells, and calculating, based on the set of output signals, the magnitudes of a plurality of triggering events within overlapping time segments.

The method may further comprise analyzing data regarding a set of output signals from the cells, and calculating, based on the set of output signals, the magnitudes of a plurality of triggering events based on a plurality of zone definitions.

Each of the cells may comprise one or more microcells, each microcell comprising:
a single-photon avalanche diode configured to detect a photon; and
a quenching arrangement configured to quench and reset the microcell.

The quenching arrangement may be configured for active quenching.

The quenching arrangement may be configured to introduce a delay between quenching and resetting the microcell.

The quenching arrangement may comprise a quenching resistor.

The output signal may be indicative of at least one particle impinging prior to the microcell being reset.

Each of the microcells may be configured to produce a plurality of output signals within the time interval.

Each of the cells may comprise a single microcell, the photomultiplier being configured to provide information correlating each microcell with an output signal produced thereby.

The method may further comprise selectively disregarding the output signal produced by one or more predetermined microcells.

The method may further comprise disregarding triggering events in which output signals were produced by fewer than a predetermined number of microcells.

### BRIEF DESCRIPTION OF THE DRAWINGS

In order to better understand the subject matter that is disclosed herein and to exemplify how it may be carried out in practice, embodiments will now be described, by way of non-limiting example only, with reference to the accompanying drawings, in which:

FIG. 1 is a schematic illustration of a scanning electron microscope according to the presently disclosed subject matter;

FIG. 2 is a schematic illustration of a particle detector of the scanning electron microscope illustrated in FIG. 1;

FIG. 3A illustrates an example of zones of a sensor surface of the particle detector illustrated in FIG. 2;

FIG. 3B schematically illustrates evaluation of a feature using the zones illustrated in FIG. 3A;

FIG. 4A illustrates another example of zones of the sensor surface of the particle detector illustrated in FIG. 2;

FIG. 4B schematically illustrates evaluation of a feature using the zones illustrated in FIG. 4A;

FIG. 5 illustrates another example of zones of the sensor surface of the particle detector illustrated in FIG. 2; and

FIG. 6 illustrates a method of evaluating one or more properties of a sample irradiated with a plurality of source particles, according to the presently disclosed subject matter.

### DETAILED DESCRIPTION OF THE INVENTION

The presently disclosed subject matter is generally directed towards photomultipliers, and systems implementing such photomultipliers for scanning the surface of a sample, including, but not limited to, scanning electron microscopes

A photomultiplier according to the presently disclosed subject matter has a sensor surface comprising a plurality of cells or microcells, and a controller which is configured to logically segment the sensor surface and to analyze output signals from the segments individually, thereby facilitating collection of impact location data with improved topographic contrast. This may facilitate, e.g., detecting the impact of a single particle, providing information regarding particle energy, counting particles, reducing or eliminating noise, in particular from an analog photomultiplier, and/or reducing or eliminating internal dark noise from digital photomultipliers.

It will be appreciated that the preceding is provided as an introductory overview to provide a general synopsis of the presently disclosed subject matter. Accordingly, it is not to be construed as limiting. Similarly, the inclusion of specific details therein, exclusion of specific details therefrom, generalizations, particularizations, etc., are not to be construed as limiting.

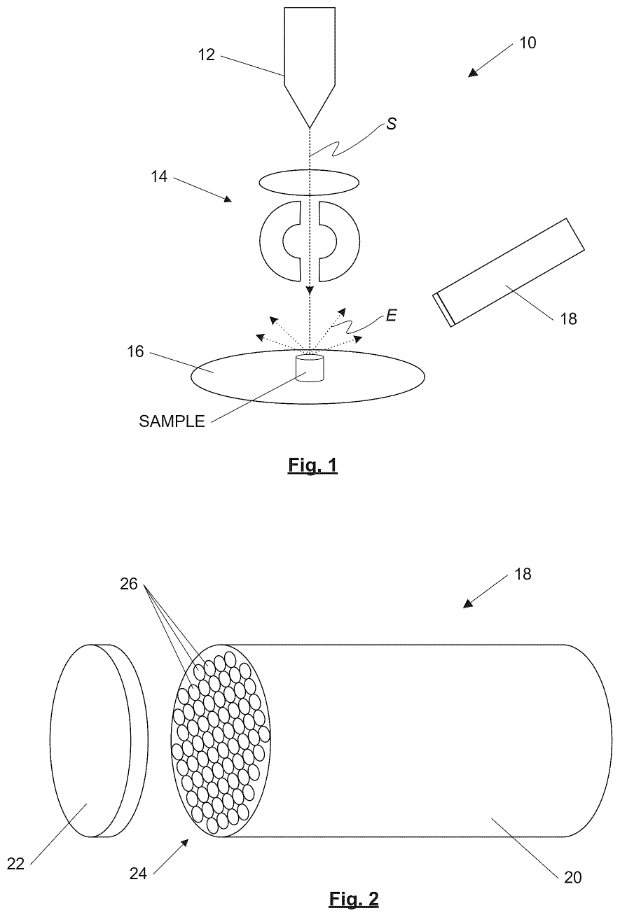

As illustrated in FIG. 1, there is provided a scanning electron microscope (SEM), which is generally indicated 10, configured to evaluate one or more predetermined properties of a sample. The SEM 10 may be configured to scan the sample by irradiating it with source particles S, typically a focused beam of electrons; to detect one or more signals comprising emitted particles E produced by the sample when impinged upon by the source particles; and to evaluate one or more properties of the sample based, inter alia, on parameters of the source particles and the emitted particles, for example as is known in the art. The emitted particles may be produced by reflection of source particles, scattering of source particles, particles which are produced from interaction of the atoms of the sample with the source particles, etc.

The SEM 10 comprises an electron gun assembly 12 configured to produce the beam of source particles and accelerate it toward the sample, a lens assembly 14 configured to direct and/or shape the beam of source particles, a stage 16 for placement thereof of the sample during scanning, and a particle detector 18 configured to detect emitted particles produced by the sample during scanning. The SEM 10 further comprises a controller configured to direct operation thereof, evaluate properties of the sample, etc. The SEM 10 and its components may be of any suitable design, for example as is known in the art.

The electron gun assembly 12 may comprise a cathode configured to emit electrons when heated or subjected to an electric field, and an anode configured to accelerate the emitted electrons to form the beam of source particles. According to some examples, the electron gun assembly 12 is a thermionic emission gun, in which the cathode comprises a filament, for example made of tungsten or lanthanum hexaboride, which is configured to emit electrons when, thereby emitting electrons. According to other examples, the electron gun assembly is a field emission gun, in which the cathode comprises a single crystal tungsten with a sharply pointed tip, for example coated with a layer of zirconium oxide.

The lens assembly 14 may include one or more electromagnetic and/or electrostatic lenses, such as condenser lenses and objective lenses, configured to manipulate the trajectory and diameter of the beam of source particles.

The particle detector 18 may be configured to detect secondary electrons emitted from the sample surface or within a few nanometers thereof, backscattered electrons produced by the elastic scattering of the source particles electrons with the atom nuclei, X-rays, or any other suitable type of emitted particles produced by the sample during scanning. One or more suitable collectors (not illustrated) may be provided to attract emitted particles toward the particle detector 18, and optionally to accelerate them before impinging thereon. It will be appreciated that while a single particle detector 18 is illustrated positioned to one side of the stage 16, this is by way of example only, and in practice more than one particle detector may be provided. For example, different particle detectors 18 may be configured to detect different types of emitted particle, may be positioned in a different locations, e.g., between the stage 16 and the electron gun assembly 12, etc., may be oriented a different angles, etc., for example as is known in the art, mutatis mutandis.

As illustrated in FIG. 2, the particle detector 18 may comprise a photomultiplier 20 configured to detect emitted particles. A scintillator 22, configured to absorb the energy of an impinging particle and to re-emit the absorbed energy as one or more photons, may be provided between the photomultiplier 20 and the stage 16, thereby converting the energy of the emitted particles into a form which is more readily detected by the photomultiplier. Accordingly, the photomultiplier 20, by detecting photons which are emitted by the scintillator 22 in proportion to the energy of the emitted particles which impinge thereupon, may be configured to indirectly detect emitted particles other than photons.

According to some examples, the photomultiplier 20 is a digital silicon photomultiplier. Accordingly, it comprises a sensor surface 24 comprising a plurality of microcells 26, for example arranged in a two-dimensional array, arranged on a silicon substrate. Each of the microcells 26 is configured to detect one or more particles impinging thereon and to produce an output signal indicative of impingement by a particle. Each of the microcells 26 is configured to operate independently of the other cells, and to generate a discrete output signal upon the absorption of a single photon. Each of the microcells 26 may further comprise a dedicated readout circuit associated therewith, thereby facilitating detecting the microcell which produced a given output signal.

According to some examples, each of the microcells 26 comprises a single-photon avalanche diode (SPAD). The SPAD may comprise a p-n junction configured to operate in Geiger mode. Each microcell 26 may further comprise a dedicated quenching arrangement configured to quench its respective SPAD and characterized by a fast recovery, thereby resetting it so that it can detect a subsequent impinging photon. According to some examples, the quenching arrangement comprises a quenching resistor connected in series with the SPAD. According to some examples, the quenching arrangement is configured for active quenching.

According to some examples, the sensor surface 24 is provided with an anti-reflective coating (not illustrated), configured to minimize the reflection of incident photons, thereby facilitating increasing the photomultiplier's photon detection efficiency. The anti-reflective coating may be provided according to any suitable design, for example as is known in the art.

The particle detector 18 further comprises a controller configured to direct operation of the particle detector. (Herein the specification and appended claims, unless otherwise indicated or clear from context, references to a “controller” refer to the controller of the particle detector.) The controller may be implemented as part of the controller of the SEM 10 mentioned above and/or implemented separately therefrom. Inter alia, the controller is configured to define a plurality of zones of the sensor surface 24 of the photomultiplier 20, wherein each of the zones comprises one or more of the microcells 26 defining a zone geometry.

The zone geometry may be characterized by the shapes of the zones, the relative position and/or arrangement of the zones, the sizes of the zones, etc. As will be described below, the zone geometry facilitates evaluating one or more properties of the sample, e.g., by measuring one or more properties of the emitted particles. According to some examples, each of the microcells 26 is associated with no more than one of the zones, i.e., there is no overlap between different zones.

The controller is further configured to calculate the magnitude of a triggering event based on the sum of the output signals which are produced by the microcells 26 within each of the zones, for example within a predetermined time interval. The time interval for a given zone may be measured, e.g., beginning from when one of the microcells 26 within the zone produces an output signal indicating that it has been impinged upon by a photon. According to examples in which the photomultiplier 20 is a digital silicon photomultiplier, e.g., as discussed above, calculating the magnitude of a triggering event based on the sum of output signal produced by microcells 26 may improve the gain invariance, as the output signals are countable and not subject to the variation inherent in the output of an analog photomultiplier, whose magnitude may be represented by the pulse height of the output signal.

According to some examples, e.g., wherein each microcell 26 comprises a SPAD and a dedicated quenching arrangement, a single microcell may produce more than one output signals within the time interval, for example if, during the time interval, it is impinged upon by a proton thereby producing a first output signal, is reset by the quenching arrangement, and is subsequently impinged upon by another proton thereby producing a second output signal.

The duration of the time interval may be based on parameters of the SEM 10 and/or of its operation. According to some examples, the duration of the time interval may be at least partially based on the operating speed of the scintillator 22. For example, a scintillator 22 having a relatively slow operating speed may be provided, for example to minimize the number of photon impingements which are missed due to multiple photons impinging a single microcell 26 before it is reset. According to some examples, the duration of the time interval may be at least partially based on the scanning speed of the SEM 10, e.g., how quickly the beam of source particles produced by the electron gun assembly 12 is moved along the surface of the sample, e.g., the time interval may be equal to the amount of time that each area of the sample which corresponds to a pixel is irradiated by source particles.

According to some examples, the controller may be configured to set a minimum threshold for triggering events. Accordingly, if a small number of microcells 26 in a zone produce output signals without being impinged upon by photons, for example in the case of self-emission (e.g., from the scintillator 22), the controller may be configured to disregard such signals thereby facilitating noise reduction.

According to some examples, the controller may be configured to selectively disregard output signals produced by one or more predetermined microcells 26, for example if it is determined to be malfunctioning.

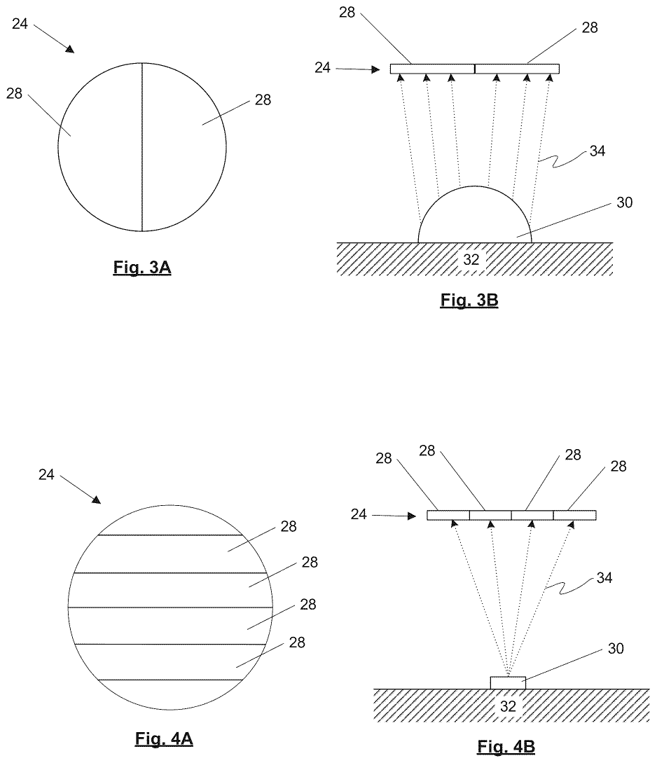

As mentioned above, the controller is configured to define a plurality of zones, each comprising one or more microcells 26, wherein the zone geometry facilitates evaluating one or more properties of the sample. According to some examples, for example as illustrated in FIG. 3A, the controller is configured to define two zones 28, each including microcells (not illustrated in FIGS. 3A and 3B) within a half of the sensor surface 24 of the photomultiplier 20, i.e., each half of the sensor surface is associated with one of the two zones. This geometry may facilitate determining features of the surface topography of the sample.

For example, as illustrated in FIG. 3B, a semispherical feature 30 on the surface of the sample 32 may produce emitted particles (indicated by their paths 34), each of which is detected by a microcell which is associated with one of the two zones 28 of the sensor surface 24 of the photomultiplier 20. The controller is thus configured to calculate the magnitudes of separate triggering events for each of the two zones 28, facilitating evaluating properties related to two sides of the feature 30 separately, thereby facilitating evaluating the feature with improved topographical contrast.

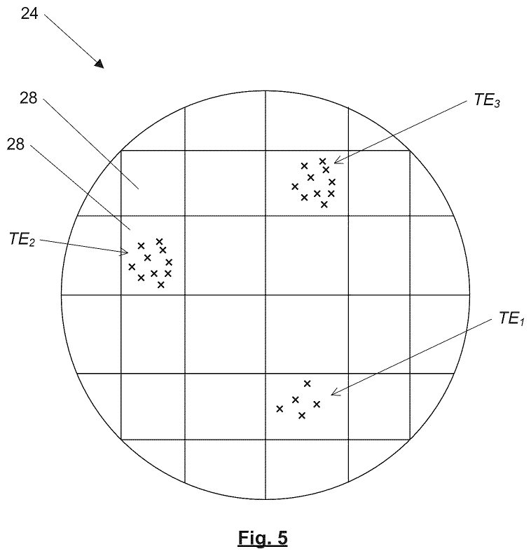

According to some examples, for example as illustrated in FIG. 4A, the controller is configured to define a plurality of zones 28 shaped as stripes on the sensor surface 24 of the photomultiplier 20. This geometry may facilitate determining features which may be evaluated based on the angle of incidence of the emitted particles.

For example, as illustrated in FIG. 4B, a feature 30 on the surface of the sample 32 may produce emitted particles which follow paths 34 having different angles. (While feature 30 is illustrated in FIG. 4B as having a geometry, this is by way of illustration only; in practice, the feature may be a portion on the surface of the sample which emits particles in a dispersive fashion in response to being irradiated by source particles.) Each of these emitted particles is detected by a microcell (not illustrated in FIGS. 4A and 4B) which is associated with one of the stripe-shaped zones 28 of the sensor surface 24 of the photomultiplier 20. The controller is thus configured to calculate the magnitudes of separate triggering events for each of the zones 28, thereby providing information as to how many emitted particles follow paths within different angular ranges. The size of each of the angular ranges may be determined based on the width of each of the stripes.

According to some examples, the controller may be configured to define a plurality of zones in order to distinguish among a plurality of triggering event which occur simultaneously, e.g., within the same time interval.

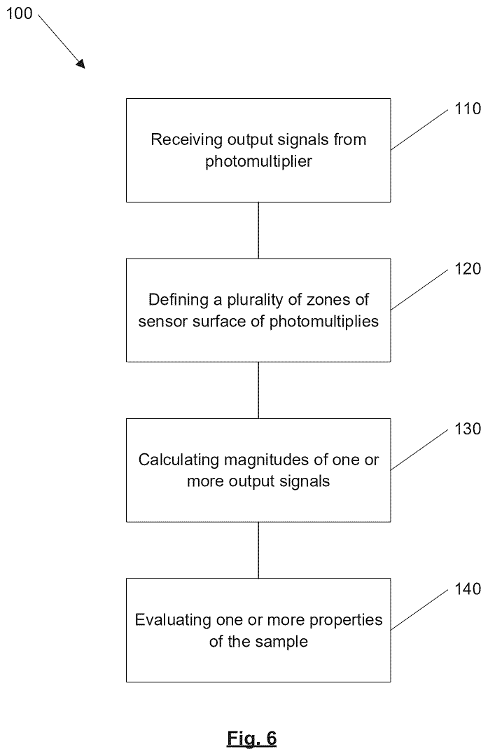

For example, as illustrated in FIG. 5, the controller may be configured to define a plurality of zones 28, each including microcells within a portion of the sensor surface 24 of the photomultiplier 20. The geometry of the zones 28 may be selected based on the expected locations where an individual emitted particle is expected to impinge, or, for example wherein a scintillator is used, the geometry of the zones may be selected such that photons emitted from the scintillator due to a single particle are expected to impinge within a single one of the zones. The controller is configured to calculate the magnitude of each of the separate triggering event which occurs when multiple locations (each indicated by x in FIG. 5) are impinged within the same time interval, i.e., to associate the output signals from each zone separately. This facilitates evaluating the energy associated with the particles which impinged on the scintillator at a higher resolution (e.g., evaluating the energy of each of the particles separately), instead of the total energy of all of the particles which impinged on the scintillator during the time interval.

For example, for impingement on the sensor surface 24 shown in FIG. 5, the controller would identify one triggering event (associated with cluster TE₁) of a relatively low energy level, and two triggering events (associated with clusters TE₂ and TE₃) each of a higher energy level. Without defining zones 28 as described, the controller would identify a single triggering event having an energy level equal to the total energy of all three triggering events identified based on the zones.

According to some examples, the feature separates emitted particles to follow different paths 28 based on their energy levels. Accordingly, the magnitude of the triggering event in each zone may relate to the number of emitted particles which, based on their energy, would follow a path associated with that zone. This facilitates evaluating, in a single reading, features based on the energy dispersion of emitted particles produced thereby when irradiated by source particles during scanning.

The controller may be configured to redefine the zones. According to some examples, the controller may be configured to define/redefine zones at the beginning of a scanning operation, for example based on a predefined property to be evaluated.

The controller may be configured to analyze data regarding a set of output signals, and to evaluate a plurality of properties based thereon. The data may be stored, and include, e.g., the time at which each microcell 26 produced an output signal, parameters of the corresponding source particles, etc., and/or it may be real-time data, i.e., the controller may be configured to simultaneously analyze output signals to evaluate a plurality of properties. According to some examples, the controller may be configured to analyze the data, or a portion thereof (e.g., relating to a region of interest on the surface of the sample), from a single scan a plurality of times, and to calculate magnitudes of different triggering events, each being based on the sum of output signals produced within a different time intervals. According to some examples, the controller may be configured to analyze the data or a portion thereof from a single scan a plurality of times, and to calculate magnitudes of different triggering events, each being based on the sum of output signals produced by microcells 26 within differently defined zones, i.e., each analysis may group the microcells into zones differently from other analyses. For example, a single set of data may be analyzed wherein zones are defined as described above with reference to and as illustrated in FIG. 3A, and then reanalyzed wherein zones are defined as described above with reference to and as illustrated in FIG. 4A, thus facilitating evaluating two different properties of the sample using a single set of scan data.

As illustrated in FIG. 6, there is provided a method, which is generally indicated at 100, of evaluating one or more properties of a sample when irradiated with a plurality of source particles, for example by a scanning electron.

In step 110 of the method 100, one or more output signals from a photomultiplier are received. The photomultiplier may be of any suitable type, for example as described above. In particular, the photomultiplier is configured to detect emitted particles produced by the sample when impinged upon by the source particles. In addition, it comprises a sensor surface having a plurality of cells. Each of the cells is configured to detect one or more particles impinging thereon. and to produce an output signal which is indicative of a quantity of impinging particles.

In step 120 of the method 100, a plurality of zones of the sensor surface are defined. Each of the zones is associated with one or more of the cells.

In step 130 of the method 100, the magnitude of one or more triggering events is calculated. The magnitude of each of the triggering events is based on the sum of the output signals which are produced by the cells within each of one or more of the zones within a predetermined time interval.

In step 140 of the method 140, the one or more properties of the sample are evaluated. The evaluation is based, at least in part, on the magnitudes of the one or more triggering events and on the geometry of the zones.

The method may be implemented by the controller of a scanning electron microscope, for example as described above with reference to and as illustrated in FIGS. 1 through 5. Moreover, details of the method 100 may be as described above with reference to and as illustrated in FIGS. 1 through 5, for example in the description of the controller of the SEM 10, mutatis mutandis.

Descriptions herein of the particle detector 18 are not to be construed as limiting all of the particle detectors provided as elements of the SEM 10; rather, an SEM according to the presently disclosed subject matter comprises at least one particle detector as described herein with reference to and as illustrated in the accompanying drawings and as recited in the appended claims, and may further comprise other particle detectors which are provided according to other designs.

Moreover, while the SEM described above with reference to and as illustrated in the accompanying drawings comprises a digital silicon photomultiplier, this is by way of example only, and in practice it may apply to other technologies as well, e.g., an analog detector such as an analog photomultiplier, a pin detector, etc., mutatis mutandis. According to some examples, the controller may be configured to separate signals produced by emitted electrons into time bins, each indicating a change in the number of simultaneously impinging emitted particles, to a single impinging emitted particle, etc.

It will be further appreciated that while the presently disclosed subject matter relates to a scanning electron microscope, a particle detector comprising a controller configured to define zones on a sensor surface and to evaluate properties of a sample based on magnitudes of triggering events within the zones may be used in other systems, for example metrology systems. Accordingly, such systems, as well as photomultiplier devices as described herein irrespective of the type of system they are provided with, constitute part of the presently disclosed subject matter, mutatis mutandis.

It will be appreciated that while herein the specification and claims the term “controller” is used with reference to a single element, it may comprise a combination of elements, which may or may not be in physical proximity to one another, without departing from the scope of the presently disclosed subject matter, mutatis mutandis. In addition, disclosure herein (including recitation in the appended claims) of a controller carrying out, being configured to carry out, or other similar language, implicitly includes other elements of the SEM 10 carrying out, being configured to carry out, etc., those functions—alone, in concert with the controller, in concert with other elements of the SEM, in concert with one or more external devices, etc.—without departing from the scope of the presently disclosed subject matter, mutatis mutandis.

It will be recognized that examples, embodiments, modifications, options, etc., described herein are to be construed as inclusive and non-limiting, i.e., two or more examples, etc., described separately herein are not to be construed as being mutually exclusive of one another or in any other way limiting, unless such is explicitly stated and/or is otherwise clear. Those skilled in the art to which this invention pertains will readily appreciate that numerous changes, variations, and modifications can be made without departing from the scope of the presently disclosed subject matter, mutatis mutandis.

1. A scanning electron microscope configured to scan a sample by irradiating it with a plurality of source particles, the scanning electron microscope comprising a particle detector comprising:
a photomultiplier configured to detect emitted particles from the sample, the photomultiplier comprising a sensor surface comprising a plurality of cells, each of the cells being configured to detect one or more particles impinging thereon and to produce an output signal indicative of a quantity of impinging particles; and
a controller configured to define a plurality of zones, each of the zones being associated with one or more of the cells, the controller being further configured to calculate a magnitude of a triggering event based on a sum of output signals produced within a predetermined time interval by the cells within each of one or more of the zones;
wherein a geometry of the zones facilitates evaluating one or more properties of the sample.

2. The scanning electron microscope according to claim 1, wherein the geometry of the zones facilitates determining a surface topography of a sample.

3. The scanning electron microscope according to claim 1, wherein the geometry of the zones facilitates determining a angle of incidence of the emitted particles.

4. The scanning electron microscope according to claim 1, wherein the geometry of the zones facilitates determining energy dispersion of a plurality of the emitted particles.

5. The scanning electron microscope according to claim 1, wherein the particle detector further comprises scintillator configured to be impinged upon by the emitted particles and to emit a number of photons proportional to an energy of the emitted particles, and wherein the photomultiplier is configured to indirectly detect the emitted particles by detecting the photons emitted by the scintillator impinging thereon.

6. (canceled)

7. The scanning electron microscope according to claim 1, wherein a duration of the time interval is at least partially based on a scanning speed of the scanning electron microscope.

8. The scanning electron microscope according to claim 7, wherein the time interval is equal to a dwell time.

9. The scanning electron microscope according to claim 1, wherein a duration of the time interval is measured from production of a first output signal by a cell within the zone.

10. The scanning electron microscope according to claim 1, wherein each of the cells is associated with no more than one of the zones.

11. The scanning electron microscope according to claim 1, wherein the controller is configured to redefine the zones.

12. The scanning electron microscope according to claim 1, wherein the controller is configured to analyze data regarding a set of output signals from the cells, and to calculate, based on the set of output signals, magnitudes of a plurality of triggering events within overlapping time segments.

13. The scanning electron microscope according to claim 1, wherein the controller is configured to analyze data regarding a set of output signals from the cells, and to calculate, based on the set of output signals, magnitudes of a plurality of triggering events based on a plurality of zone definitions.

14. The scanning electron microscope according to claim 1, wherein each of the cells comprises one or more microcells, each microcell comprising:
a single-photon avalanche diode configured to detect a photon; and
a quenching arrangement configured to quench and reset the microcell.

15. The scanning electron microscope according to claim 14, the quenching arrangement being configured for active quenching.

16-17. (canceled)

18. The scanning electron microscope according to claim 14, wherein the output signal is indicative of at least one particle impinging prior to the microcell being reset.

19. The scanning electron microscope according to claim 14, wherein each of the microcells is configured to produce a plurality of output signals within the time interval.

20. The scanning electron microscope according to claim 14, wherein each of the cells comprises a single microcell, and the photomultiplier is configured to provide information correlating each microcell with an output signal produced thereby.

21. The scanning electron microscope according to claim 20, the controller being configured to selectively disregard the output signal produced by one or more predetermined microcells.

22. The scanning electron microscope according to claim 20, the controller being configured to disregard triggering events in which output signals were produced by fewer than a predetermined number of microcells.

23. A method for evaluating one or more properties of a sample when irradiated by a scanning electron microscope with a plurality of source particles, the method comprising:
receiving one or more output signals from a photomultiplier, the photomultiplier being configured to detect emitted particles produced by the sample when impinged upon by the source particles, the photomultiplier comprising a sensor surface comprising a plurality of cells, each of the cells being configured to detect one or more particles impinging thereon and to produce one of the output signals being indicative of a quantity of impinging particles;
defining a plurality of zones of the sensor surface, each of the zones being associated with one or more of the cells;
calculating a magnitude of one or more triggering event, the magnitude of each triggering event being based on a sum of output signals produced within a predetermined time interval by the cells within each of one or more of the zones; and
evaluating the one or more properties of the sample based on magnitudes of the one or more triggering events and on a geometry of the zones.

24-44. (canceled)
